(19) United States
(12) Patent Application Publication
(10) Pub. No.: US 2026/0112407 A1
(43) Pub. Date: Apr. 23, 2026

(54) Buffer Device for Combining and Splitting Pseudo Channel Data Strobes (DQS)

(71) Applicant: Advanced Micro Devices, Inc., Santa Clara, CA (US)

(72) Inventors: Aaron John Nygren, Boise, ID (US); Christopher Edward Cox, Placerville, CA (US); Edoardo Prete, Arlington, MA (US); Anwar Parvez Kashem, Sudbury, MA (US)

(73) Assignee: Advanced Micro Devices, Inc., Santa Clara, CA (US)

(21) Appl. No.: 19/362,946

(22) Filed: Oct. 20, 2025

Related U.S. Application Data
(60) Provisional application No. 63/709,931, filed on Oct. 21, 2024.

(51) Int. Cl. G11C 11/4093; G11C 11/4076; G11C 11/4096

(52) U.S. Cl. CPC G11C 11/4093; G11C 11/4076; G11C 11/4096

(57) ABSTRACT

A buffer device for combining and splitting data strobes (DQS) for pseudo channels in memory systems is described. In one or more implementations, a buffer device includes strobe logic configured to combine multiple data strobes for separate pseudo channels into a combined data strobe for transmission to memory chips connected to the buffer device, and split multiple combined data strobes received from the memory chips into separate data strobes per pseudo channel for transmission to a system on chip. The buffer device is positioned between the memory chips and the system on chip to manage data strobe signals bidirectionally while maintaining pseudo channel independence on the system side and shared strobe functionality on the memory side.

### RELATED APPLICATION

This application claims priority to U.S. Provisional Application Ser. No. 63/709,931, filed 21 Oct. 2024, titled “Buffer Device for Combining and Splitting Pseudo Channel Data Strobes (DQS),” the disclosure of which is incorporated by reference herein in its entirety.

### BACKGROUND

Dual In-Line Memory Modules (DIMMs) are circuit boards that hold dynamic random-access memory (DRAM) chips, which serve as the memory for many computers. Over time, advancements in DIMM technology (e.g., DDR4 to DDR5)—such as increases in speed, higher data transfer rates, and larger storage capacities—have improved computer performance, enabling faster data processing, smoother multitasking, and support for memory-intensive applications like virtual machines, large-scale databases, and artificial intelligence workloads. These innovations can also contribute to energy efficiency, which reduces power consumption while delivering higher performance.

### BRIEF DESCRIPTION OF THE DRAWINGS

FIG. 1 is a block diagram of a processing system configured to execute one or more applications.

FIG. 2 is a block diagram of a non-limiting example of a memory system.

FIG. 3 is a block diagram of a non-limiting example of pins of multiple memory die of a memory chip, such as a stacked DRAM.

FIG. 4 is a block diagram of a non-limiting example of a buffer configured to combine strobes for multiple pseudo channels into a combined strobe for memory chips and to separate strobes for the multiple pseudo channels for a connected system, e.g., a system on chip (SoC).

FIG. 5 depicts a procedure in an example implementation of a buffer device for combining and splitting pseudo channel data strobes.

### DETAILED DESCRIPTION

Modern memory architectures, particularly those implementing stacked DRAM with multiple memory die supporting pseudo channels, face a variety of challenges when sharing data strobe (DQS) signals between pseudo channels. These challenges include timing complexities, signal integrity issues, and pin count constraints that become increasingly problematic at higher data transfer rates and greater storage capacities.

A buffer device for combining and splitting pseudo channel data strobes (DQS) is described. The buffer device addresses the noted challenges by converting data strobe (DQS) signals between memory chips and a host system, such as a system on chip (SoC). In one or more implementations, the buffer includes strobe combination logic that combines multiple data strobes for separate pseudo channels into a combined data strobe utilized by memory chips connected to the buffer device. Additionally, the buffer includes strobe splitting logic to separate data strobes received from the memory chips into individual data strobe signals per pseudo channel for transmission with the host.

This bidirectional approach provides advantages over conventional systems. During memory write operations, for instance, the buffer combines separate data strobe signals from the memory controller into a combined data strobe that the memory chips use to latch data received at their data pins. Conversely, during memory read operations, the buffer splits the combined data strobe signals from the memory chips into separate data strobes per pseudo channel, enabling the memory controller to use these independent timing references for data validation.

The buffer device is configurable to convert between different ratios of data pins to strobe pins on each side of the buffer. On the memory chip side, each memory chip may provide a relatively small number of data pins with corresponding data strobe pins, resulting in a low ratio of data pins to strobe pins, e.g., 2 to 1 or 4 to 1. However, when the buffer consolidates signals from multiple memory chips, the buffer can implement a higher ratio of data pins to strobe signals on the system side (e.g., 8 to 1 or 16 to 1), effectively reducing the total number of strobe connections required to the system on chip.

This approach to handling data strobe signals in multi-channel memory architectures is an improvement over conventional techniques. By providing separate data strobe signals per pseudo channel to a host while maintaining shared strobe functionality on the memory side, the buffer simplifies host-side timing, improves signal integrity, reduces physical connection requirements, and enables greater flexibility of memory systems.

In some aspects, the techniques described herein relate to a buffer device, including: strobe combination logic configured to combine multiple data strobes for separate pseudo channels into a combined data strobe utilized by memory chips connected to the buffer device; and strobe splitting logic configured to split multiple combined data strobes for the separate pseudo channels into separate data strobes per pseudo channel for a system on chip (SoC), wherein the buffer device is configured to provide the separate data strobes per pseudo channel to the SoC.

In some aspects, the techniques described herein relate to a buffer device, wherein the buffer device is included on a dual in-line memory module (DIMM).

In some aspects, the techniques described herein relate to a buffer device, wherein the DIMM supports a multi-channel architecture for accessing the memory chips.

In some aspects, the techniques described herein relate to a buffer device, wherein the buffer device is integrated into a package of a memory chip.

In some aspects, the techniques described herein relate to a buffer device, wherein the combined data strobe is used by the memory chips with a memory write to latch data received at one or more data pins of the memory chips, wherein the data is received from a memory controller.

In some aspects, the techniques described herein relate to a buffer device, wherein the combined data strobe is used with a memory read to validate data sent over one or more data pins of the memory chips, the data sent to a memory controller from the one or more data pins.

In some aspects, the techniques described herein relate to a buffer device, wherein the multiple combined data strobes are received by the buffer device from a memory controller and the combined data strobe is provided to at least one of the memory chips connected to the buffer device.

In some aspects, the techniques described herein relate to a buffer device, wherein the strobe combination logic is configured to adjust timing of the combined data strobe to accommodate timing offsets between the separate pseudo channels.

In some aspects, the techniques described herein relate to a buffer device, wherein adjusting the timing of the combined data strobe includes extending a duration of the combined data strobe to encompass timing windows of the separate pseudo channels.

In some aspects, the techniques described herein relate to a buffer device, wherein the strobe combination logic is configured to synchronize timing of the multiple data strobes from the separate pseudo channels before combining the multiple data strobes into the combined data strobe.

In some aspects, the techniques described herein relate to a buffer device, wherein the strobe splitting logic is configured to generate the separate data strobes based on observed command sequences issued to the separate pseudo channels.

In some aspects, the techniques described herein relate to a buffer device, wherein the buffer device is configured to convert between a first ratio of data pins to strobe pins on a memory chip side of the buffer device and a second ratio of data pins to strobe pins on a system side of the buffer device, wherein the first ratio is lower than the second ratio to consolidate signals from multiple memory chips.

In some aspects, the techniques described herein relate to a buffer device, wherein a range of the first ratio includes 2:1 to 4:1 data pins to strobe pins on the memory chip side and a range of the second ratio includes 8:1 to 16:1 data pins to strobe pins on the system side.

In some aspects, the techniques described herein relate to a method including: combining, by a buffer device, multiple data strobes for separate pseudo channels into a combined data strobe for data transfer with memory chips connected to the buffer device; and splitting, by the buffer device, multiple combined data strobes received from the memory chips into separate data strobes per pseudo channel for data transfer with a system on chip (SoC).

In some aspects, the techniques described herein relate to a method, further including adjusting a timing of the combined data strobe to accommodate timing offsets between the separate pseudo channels.

In some aspects, the techniques described herein relate to a method, wherein the combined data strobe is used by the memory chips with a memory write operation to latch data received at one or more data pins of the memory chips.

In some aspects, the techniques described herein relate to a method, wherein the combined data strobe is used with a memory read operation to validate data sent over one or more data pins of the memory chips to a memory controller.

In some aspects, the techniques described herein relate to a method, wherein splitting the multiple combined data strobes includes observing command sequences to determine strobe splitting details based on timing differences and logic value differences between the multiple combined data strobes.

In some aspects, the techniques described herein relate to a memory system including: one or more memory chips, each memory chip including multiple memory die configured to support multiple pseudo channels, wherein each memory chip includes data pins and data strobe pins; and a buffer device positioned between the one or more memory chips and a system on chip (SoC), the buffer device configured to: combine multiple data strobe signals for separate pseudo channels into a combined data strobe signal utilized by the one or more memory chips; and split data multiple combined strobe signals from the one or more memory chips into separate data strobe signals per pseudo channel for transmission to the SoC.

In some aspects, the techniques described herein relate to a memory system, wherein the one or more memory chips include dynamic random-access memory (DRAM) chips arranged in a stacked configuration.

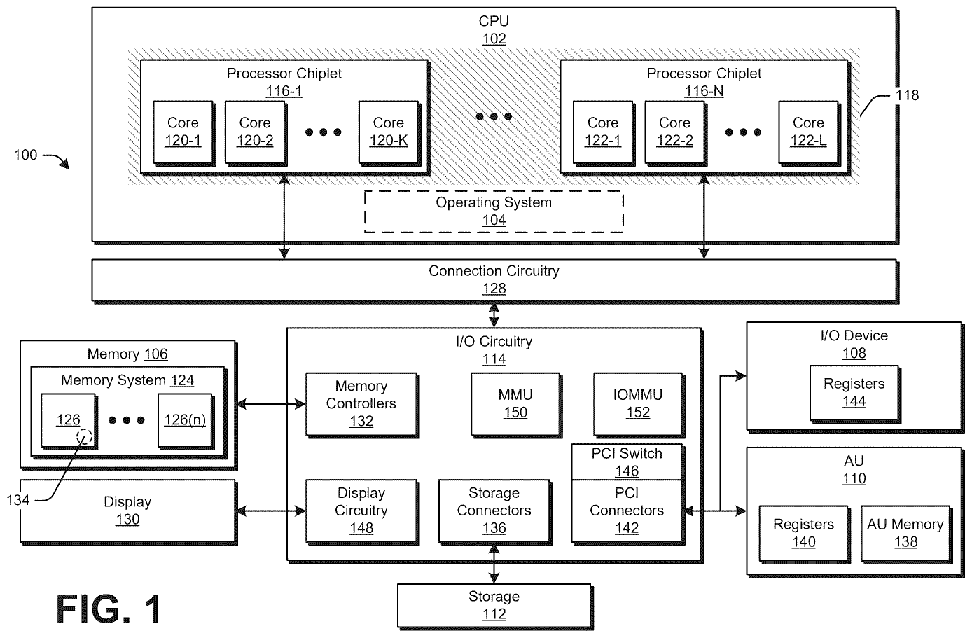

FIG. 1 is a block diagram of a processing system configured to execute one or more applications, in accordance with one or more implementations.

FIG. 1 includes a processing system 100 configured to execute one or more applications, such as compute applications (e.g., machine-learning applications, neural network applications, high-performance computing applications, databasing applications, gaming applications), graphics applications, and the like. Examples of devices in which the processing system is implemented include, but are not limited to, a server computer, a personal computer (e.g., a desktop or tower computer), a smartphone or other wireless phone, a tablet or phablet computer, a notebook computer, a laptop computer, a wearable device (e.g., a smartwatch, an augmented reality headset or device, a virtual reality headset or device), an entertainment device (e.g., a gaming console, a portable gaming device, a streaming media player, a digital video recorder, a music or other audio playback device, a television, a set-top box), an Internet of Things (IoT) device, an automotive computer or computer for another type of vehicle, a networking device, a medical device or system, and other computing devices or systems.

In the illustrated example, the processing system 100 includes a central processing unit (CPU) 102. In one or more implementations, the CPU 102 is configured to run an operating system (OS) 104 that manages the execution of applications. For example, the OS 104 is configured to schedule the execution of tasks (e.g., instructions) for applications, allocate portions of resources (e.g., system memory 106, CPU 102, input/output (I/O) device 108, accelerator unit (AU) 110, storage 112, I/O circuitry 114) for the execution of tasks for the applications, provide an interface to I/O devices (e.g., I/O device 108) for the applications, or any combination thereof.

The CPU 102 includes one or more processor chiplets 116, which are communicatively coupled together by a data fabric 118 in one or more implementations.

Each of the processor chiplets 116, for example, includes one or more processor cores 120, 122 configured to concurrently execute one or more series of instructions, also referred to herein as “threads,” for an application. Further, the data fabric 118 communicatively couples each processor chiplet 116-N of the CPU 102 such that each processor core (e.g., processor cores 120) of a first processor chiplet (e.g., 116-1) is communicatively coupled to each processor core (e.g., processor cores 122) of one or more other processor chiplets 116. Though the example embodiment presented in FIG. 1 shows a first processor chiplet (116-1) having three processor cores (120-1, 120-2, 120-K) representing a K number of processor cores 120 and a second processor chiplet (116-N) having three processor cores (e.g., 122-1, 122-2, 122-L) representing an L number of processor cores 122, in other implementations (L being an integer number greater than or equal to one), each processor chiplet 116 may have any number of processor cores 120, 122. For example, each processor chiplet 116 can have the same number of processor cores 120, 122 as one or more other processor chiplets 116, a different number of processor cores 120, 122 as one or more other processor chiplets 116, or both.

Examples of connections which are usable to implement data fabric include but are not limited to, buses (e.g., a data bus, a system, an address bus), interconnects, memory channels, through silicon vias, traces, and planes. Other example connections include optical connections, fiber optic connections, and/or connections or links based on quantum entanglement.

In this example, the memory 106 is depicted with memory system 124, which is depicted with memory chips 126. In one or more implementations, the memory system 124 corresponds to a type of memory configured according to a standard, such as according to a JEDEC (Joint Electron Device Engineering Council) standard. Additionally or alternatively, the memory system 124 is a memory module, such as a dual in-line memory module (DIMM). In at least one example, for instance, the memory system 124 is a DIMM configured according to a JEDEC standard applicable to DIMMs, such as according to a double data rate #(DDR #) standard, where the ‘#’ symbol corresponds to an integer. In one or more implementations, the memory chips 126 are dynamic random-access memory (DRAM) chips, which are coupled to a printed circuit board forming the memory system 124. The memory system 124 is depicted with memory chip 126 and memory chip 126(n), where n represents any integer greater than or equal to 1. This represents that the memory system 124 is equipped with multiple memory chips 126 and may include various numbers of the memory chips 126. Although only one memory system 124 is depicted, in one or more implementations, the system 100 may include multiple memory systems 124, such as multiple memory systems 124 arranged in a stacked configuration. Additionally, or alternatively, multiple memory systems 124 arranged in a stack may also be arranged in a stack with one or more compute units, such as with one or more CPUs or GPUs and/or portions of a CPU or GPU, e.g., cores.

Additionally, within the processing system 100, the CPU 102 is communicatively coupled to an I/O circuitry 114 by a connection circuitry 128. For example, each processor chiplet 116 of the CPU 102 is communicatively coupled to the I/O circuitry 114 by the connection circuitry 128. The connection circuitry 128 includes, for example, one or more data fabrics, buses, buffers, queues, and the like. The I/O circuitry 114 is configured to facilitate communications between two or more components of the processing system 100 such as between the CPU 102, system memory 106, display 130, universal serial bus (USB) devices, peripheral component interconnect (PCI) devices (e.g., I/O device 108, AU 110), storage 112, and the like.

As an example, system memory 106 includes any combination of one or more volatile memories and/or one or more non-volatile memories, examples of which include dynamic random-access memory (DRAM), static random-access memory (SRAM), non-volatile RAM, and the like. To manage access to the system memory 106, such as by the CPU 102, the I/O device 108, the AU 110, and/or any other components, the I/O circuitry 114 includes one or more memory controllers 132. These memory controllers 132, for example, include circuitry configured to manage and fulfill memory access requests issued from the CPU 102, the I/O device 108, the AU 110, and/or any other device of the processing system. Examples of such requests include read requests, write requests, fetch requests, pre-fetch requests, and so on. That is to say, these memory controllers 132 are configured to manage access to the data stored at one or more memory addresses within the system memory 106, such as by CPU 102, the I/O device 108, and/or the AU 110. Although the memory controllers 132 are depicted separate from the memory system 124 in this example, in one or more implementations, one or more such memory controllers are included as part of the memory system 124, e.g., incorporated on or in or otherwise attached to the printed circuit board to which the memory chips 126 are mounted.

When an application is to be executed by processing system 100, the OS 104 running on the CPU 102 is configured to load at least a portion of program code 134 (e.g., an executable file) associated with the application from, for example, a storage 112 into system memory 106, such as into one or more memory chips 126 of the memory system 124. This storage 112, for example, includes a non-volatile storage such as a flash memory, solid-state memory, hard disk, optical disc, or the like configured to store program code 134 for one or more applications.

To facilitate communication between the storage 112 and other components of processing system 100, the I/O circuitry 114 includes one or more storage connectors 136 (e.g., universal serial bus (USB) connectors, serial AT attachment (SATA) connectors, PCI Express (PCIe) connectors) configured to communicatively couple storage 112 to the I/O circuitry 114 such that I/O circuitry 114 is capable of routing signals to and from the storage 112 to one or more other components of the processing system 100.

In association with executing an application, in one or more scenarios, the CPU 102 is configured to issue one or more instructions (e.g., threads) to be executed for an application to the AU 110. The AU 110 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable gate arrays (FPGAs)), or any combination thereof.

In at least one example, the AU 110 includes one or more compute units that concurrently execute one or more threads of an application and store data resulting from the execution of these threads in AU memory 138. This AU memory 138, for example, includes any combination of one or more volatile memories and/or non-volatile memories, examples of which include caches, video RAM (VRAM), or the like. In one or more implementations, these compute units are also configured to execute these threads based on the data stored in one or more physical registers 140 of the AU 110. Alternatively, or additionally, the AU 110 includes memory like the memory system 124, e.g., one or more memory modules.

To facilitate communication between the AU 110 and one or more other components of processing system 100, the I/O circuitry 114 includes or is otherwise connected to one or more connectors, such as PCI connectors 142 (e.g., PCIe connectors) each including circuitry configured to communicatively couple the AU 110 to the I/O circuitry such that the I/O circuitry 114 is capable of routing signals to and from the AU 110 to one or more other components of the processing system 100. Further, the PCIe connectors 142 are configured to communicatively couple the I/O device 108 to the I/O circuitry 114 such that the I/O circuitry 114 is capable of routing signals to and from the I/O device 108 to one or more other components of the processing system 100.

By way of example and not limitation, the I/O device 108 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 108 is configured to execute one or more operations, tasks, instructions, or any combination thereof based on one or more physical registers 144 of the I/O device 108. In one or more implementations, such physical registers 144 are configured to maintain data (e.g., operands, instructions, values, variables) indicating one or more operations, tasks, or instructions to be performed by the I/O device 108.

To manage communication between components of the processing system 100 (e.g., AU 110, I/O device 108) that are connected to PCI connectors 142, and one or more other components of the processing system 100, the I/O circuitry 114 includes PCI switch 146. The PCI switch 146, for example, includes circuitry configured to route packets to and from the components of the processing system 100 connected to the PCI connectors 142 as well as to the other components of the processing system 100. As an example, based on address data indicated in a packet received from a first component (e.g., CPU 102), the PCI switch 146 routes the packet to a corresponding component (e.g., AU 110) connected to the PCI connectors 142.

Based on the processing system 100 executing a graphics application, for instance, the CPU 102, the AU 110, or both are configured to execute one or more instructions (e.g., draw calls) such that a scene including one or more graphics objects is rendered. After rendering such a scene, the processing system 100 stores the scene in the storage 112, displays the scene on the display 130, or both. The display 130, for example, includes a cathode-ray tube (CRT) display, liquid crystal display (LCD), light emitting diode (LED) display, organic light emitting diode (OLED) display, or any combination thereof. To enable the processing system 100 to display a scene on the display 130, the I/O circuitry 114 includes display circuitry 148. The display circuitry 148, for example, includes high-definition multimedia interface (HDMI) connectors, DisplayPort connectors, digital visual interface (DVI) connectors, USB connectors, and the like, each including circuitry configured to communicatively couple the display 130 to the I/O circuitry 114. Additionally or alternatively, the display circuitry 148 includes circuitry configured to manage the display of one or more scenes on the display 130 such as display controllers, buffers, memory, or any combination thereof.

Further, the CPU 102, the AU 110, or both are configured to concurrently run one or more virtual machines (VMs), which are each configured to execute one or more corresponding applications. To manage communications between such VMs and the underlying resources of the processing system 100, such as any one or more components of processing system 100, including the CPU 102, the I/O device 108, the AU 110, and the system memory 106, the I/O circuitry 114 includes memory management unit (MMU) 146 and input-output memory management unit (IOMMU) 148. The MMU 150 includes, for example, circuitry configured to manage memory requests, such as from the CPU 102 to the system memory 106. For example, the MMU 150 is configured to handle memory requests issued from the CPU 102 and associated with a VM running on the CPU 102. These memory requests, for example, request access to read, write, fetch, or pre-fetch data residing at one or more virtual addresses (e.g., guest virtual addresses) each indicating one or more portions (e.g., physical memory addresses) of the system memory 106. Based on receiving a memory request from the CPU 102, the MMU 150 is configured to translate the virtual address indicated in the memory request to a physical address in the system memory 106 and to fulfill the request. The IOMMU 152 includes, for example, circuitry configured to manage memory requests (memory-mapped I/O (MMIO) requests) from the CPU 102 to the I/O device 108, the AU 110, or both, and to manage memory requests (direct memory access (DMA) requests) from the I/O device 108 or the AU 110 to the system memory 106. For example, to access the registers 144 of the I/O device 108, the registers 140 of the AU 110, and/or the AU memory 138, the CPU 102 issues one or more MMIO requests. Such MMIO requests each request access to read, write, fetch, or pre-fetch data residing at one or more virtual addresses (e.g., guest virtual addresses) which each represent at least a portion of the registers 144 of the I/O device 108, the registers 140 of the AU 110, or the AU memory 138, respectively. As another example, to access the system memory 106 without using the CPU 102, the I/O device 108, the AU 110, or both are configured to issue one or more DMA requests. Such DMA requests each request access to read, write, fetch, or pre-fetch data residing at one or more virtual addresses (e.g., device virtual addresses) which each represent at least a portion of the system memory 106. Based on receiving an MMIO request or DMA request, the IOMMU 152 is configured to translate the virtual address indicated in the MMIO or DMA request to a physical address and fulfill the request.

In variations, the processing system 100 can include any combination of the components depicted and described. For example, in at least one variation, the processing system 100 does not include one or more of the components depicted and described in relation to FIG. 1. Additionally or alternatively, in at least one variation, the processing system 100 includes additional and/or different components from those depicted. The processing system 100 is configurable in a variety of ways with different combinations of components in accordance with the described techniques.

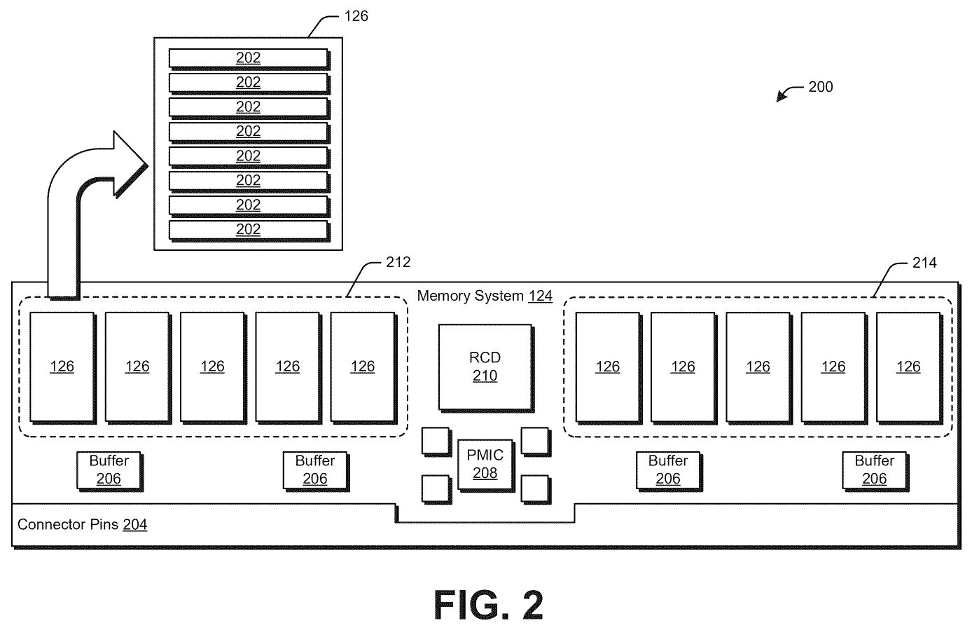

FIG. 2 is a block diagram of a non-limiting example 200 of a memory system. The illustrated example includes the memory system 124 having a plurality of the memory chips 126.

In one or more implementations, the memory system 124 is an in-line memory module, and each of the memory chips 126 is dynamic random-access memory (DRAM), such as synchronous dynamic random-access memory SDRAM. By way of example, the memory system 124 is a dual in-line memory module (DIMM). When configured as an in-line memory module, for instance, the memory system 124 includes the memory chips 126 (DRAMs) mounted communicably to a printed circuit board on one or both sides (i.e., front and/or back) of the printed circuit board. In one or more implementations, the memory system 124 is standardized, such that various aspects of the memory system 124 and/or the memory chips 126 conform to a standard, e.g., a JEDEC standard. Although ten memory chips 126 are depicted in the illustrated example, the memory system 124 can include any different integer number of memory chips 126 in accordance with the described techniques, e.g., two (2), eight (8), nine (9), twelve (12), fifteen (15), sixteen (16), twenty (20), twenty-four (24), twenty-seven (27), thirty (30), and so on.

In one or more implementations, at least one of the memory chips 126 includes a plurality of memory die 202, such as memory die arranged in a “stacked” or “3D” configuration. In connection with DRAM technology, such an arrangement may be referred to as “stacked DRAM,” “3D stacked DRAM,” or a “3D DRAM stack.” Thus, in one or more implementations, at least one of the memory chips 126 is a stacked DRAM. This also means that each of the memory chips 126 may comprise a stack of memory die 202 in at least one variation. For example, each of the memory chips 126 is a stacked DRAM. Although the view of the memory chips 126 with the stack of memory die 202 includes eight memory die, in variations, any of the memory chips 126 may have a different integer number of memory die, e.g., four (4), five (5), ten (10), and so forth, without departing from the spirit or scope of the described techniques.

The memory system 124 also includes connector pins 204. The connector pins 204 serve as electrical connectors that are used to communicably link the memory system 124 to at least one other component of a system (e.g., of the system 100), allowing transfer over the link, for example, of data, address signals, power, control signals, command/address signals, and so on, between the memory system 124 and the rest of the system. In at least one implementation, the connector pins 204 electrically connect the memory system 124 to a motherboard or “host”. The connector pins 204 can include one or more of data transfer pins, address pins, power and ground pins, control pins, and error correcting code (ECC) pins, to name just a few. The memory system 124 may include varying integer numbers of the connector pins 204 arranged in various layouts (e.g., with double rows of pins, with offset pins, with notches or cutouts in the arrangement) and having any of a variety of shapes (e.g., rectangular, triangular, rounded rectangle, etc.), without departing from the described techniques. Additionally, the connector pins 204 may be formed of any of a variety of materials including, for example, gold and/or gold plating, which is a suitable conductor of electricity and is resistant to corrosion. In variations, one or more notches or cutouts may be present in the connector pins 204, e.g., on an outboard side of the memory system 124 resulting in a gap of space (not shown) between pins and/or on an inboard side of the memory system 124 resulting in a gap (not shown) filled with at least a portion of the printed circuit board (e.g., silicon and/or other components of a printed circuit board).

In this example, the memory system 124 is also depicted with buffer(s) 206, power management integrated circuit 208 (referred to as PMIC 208), and registered clock driver 210 (referred to as RCD 210). It is to be appreciated that in variations the memory system 124 includes different/additional components (e.g., one or more memory controllers), does not include one or more of the depicted and/or described components, includes different numbers of the depicted and/or described components (e.g., a different number of buffer(s) 206), and so on, without departing from the spirit or scope of the described techniques.

The buffer(s) 206 of the memory system 124 may include one or more types of buffers and/or buffers that perform any of a variety of functions for the memory system 124 (e.g., programmed to perform the different functions and/or configured in hardware to perform such different functions), such as data buffers, input buffers, output buffers, and so on. In one example, for instance, a buffer may be connected to two of the memory chips 126 on one side and to a system on chip (SoC) (e.g., the system 100) on the other side, enabling the memory chips 126 to communicate with the system in a time sequenced fashion. On a host side interface of the buffer to the system (e.g., an SoC), the buffer may effectively multiply a frequency up, doubling the bandwidth by having two devices (e.g., memory chips 126) on the other side of the buffer and supplying twice the data that is then serialized to the host (i.e., the system) at twice the speed.

In another example, a buffer may be programmed or otherwise configured to, in one direction of communication between the memory chips 126 (and/or one or more other components of the memory system 124) and one or more system components to which the memory system 124 is connected (e.g., a “host”), combine signals and/or data, and in an opposite direction of communication separate signals and/or data. For signals and or data routed from the memory chips 126 to a host, for instance, at least one buffer 206 may separate the signals and/or data for further transmission to the host. For signals and or data routed in the opposite direction, e.g., from the host to the memory chips 126, though, the at least one buffer 206 may combine the signals and/or data into one or more channels for further routing to the memory chips 126.

In one or more implementations, the memory system 124 is configured to support a multi-channel architecture, where the memory chips 126 are accessed over multiple channels of the architecture, e.g., over two or more channels. For example, a first group or cluster of the memory chips 126 is accessed over a first channel (e.g., Channel A), and a second group or cluster of the memory chips 126 is accessed over a second channel (e.g., Channel B). It is to be appreciated that the memory system 124 may support access over more than two channels, e.g., a third channel (e.g., Channel C), a fourth channel (e.g., Channel D), and so on.

While in some implementations an individual memory chip 126 is accessed over just one channel of the multiple channels (e.g., all the memory die 202 of the individual memory chip are accessed over the one channel), in variations, an individual memory chip 126 may be accessed over at least two of the multiple memory channels (e.g., a portion of the memory die 202 of the individual chip is accessed over a first channel and a different portion of the memory die 202 of the individual chip is accessed over a second channel). In at least one variation, the memory system 124 supports a combination of such access, such that a first set of the memory chips 126 (at least one memory chip) is accessed entirely by a first channel, a second set of the memory chips 126 (at least one memory chip) is accessed entirely by a second channel, and a third set of the memory chips 126 (at least one memory chip) is accessed by both the first channel and the second channel (i.e., split access). In one or more implementations, such split access may be handled by a buffer 206 that is configured to facilitate access to the appropriate memory die of the memory chips 126 with the split access, such as for memory reads and/or memory writes. One or more of the memory chips 126 may be configured for such split access in scenarios where the memory system 124 is configured for error correcting code (ECC) use, for example. It is to be appreciated that access via multiple channels to the memory chips 126 may be arranged in a variety of ways for different numbers of channels, and include, for instance, one or more memory chips 126 that are accessed entirely over just one of the multiple channels and one or more memory chips 126 that are accessed over at least two of the channels (e.g., over at least a first channel and a second channel), without departing from the described techniques.

The illustrated example is depicted with an indication of a first cluster 212 of the memory chips 126 and an indication of a second cluster 214 of the memory chips 126. In at least one implementation, the first cluster 212 of the memory chips 126 is accessed over a first channel (and via respective buffer 206 and connector pins 204), and the second cluster 214 of the memory chips 126 is accessed over a second channel (and via respective buffer 206 and connector pins 204). For instance, read and write accesses of the first cluster 212 of memory chips 126 are serviced over the first channel, while read and write accesses of the second cluster 214 of memory chips 126 are serviced over the second channel. In at least one variation, while the memory chips 126 are clustered into multiple clusters, the clustering may not correspond to channels over which the memory chips 126 are accessed. Instead, for instance, despite being physically clustered on a printed circuit board, each of the memory chips 126 may be accessed over multiple channels (e.g., two channels), where one or more of the memory die 202 of an individual memory chip are accessed over a first channel, and one or more other memory die 202 of that same induvial memory chip are accessed over at least one other channel.

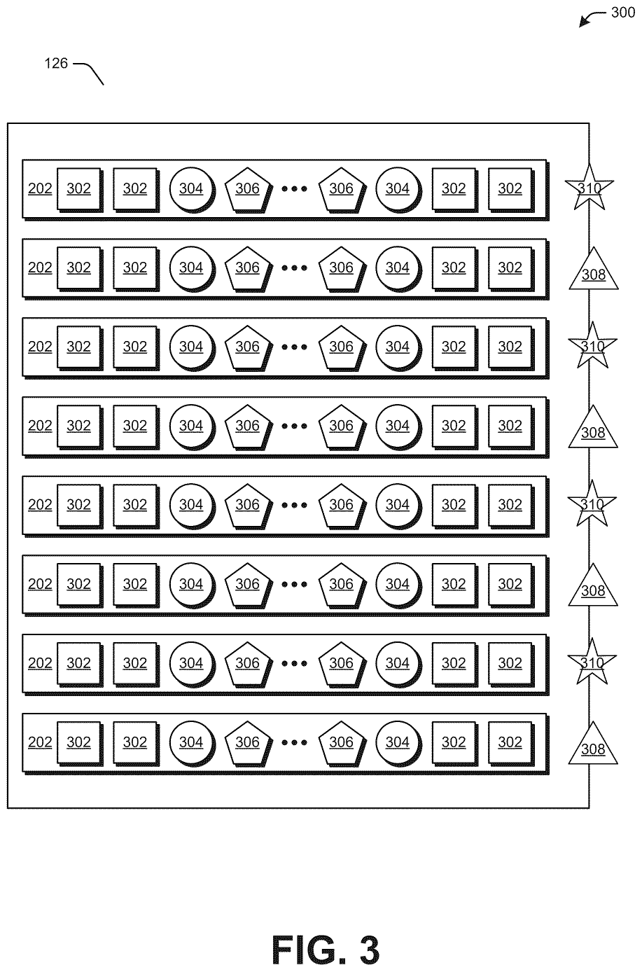

FIG. 3 is a block diagram of a non-limiting example 300 of pins of multiple memory die of a memory chip, such as a stacked DRAM.

This figure depicts an example of one of the memory chips 126 having multiple memory die 202, such as when configured as a stacked DRAM. Here, each of the memory die 202 is shown with multiple types of pins 302, 304, 306. As an example, the pins 302 correspond to data pins (DQ pins), the pins 304 correspond to command/address pins (CA pins), and the pins 306 correspond to data strobe pins (DQS pins) of the memory die 202. In variations, the memory die 202 may have different numbers of pins, e.g., more pins or fewer pins. Additionally or alternatively, the memory die 202 may include different and/or additional types of pins (or pins configured for different functionality), examples of which include data mask (DM) pins, clock (CK) pins, chip select (CS) pins, and any other pin types used with DRAM.

In one or more implementations, the data (DQ) pins are bidirectional lines that transmit data during read memory accesses and write memory accesses, such as with a data strobe pin (DQS pin) acting as a strobe signal that indicates when the data on the DQ pins is valid. In other words, the data (DQ) pins are part of a memory interface, which allows data to be transferred to and from memory, such as on edges of a clock signal. As part of a DDR interface, for instance, the data (DQ) pins allow data to be transferred in connection with memory access requests (e.g., memory reads and memory writes) on both the rising and falling edges of the clock signal, doubling the effective data rate. In connection with a read memory request, the memory die 202 send data stored therein out on the data (DQ pins), and the DQS signal from the DQS pins 306 indicates when the data is valid. In connection with a write memory request, a memory controller (e.g., a buffer within the memory chip 126 package or an external controller) sends data on the data (DQ) pins to be written to the memory die 202, and the DQS signal received by the DQS pins 306 indicates when the data is valid for the memory die 202 to latch.

By way of contrast, command/address (CA) pins are electrical connections that carry commands and addresses to the memory die 202, enabling a memory controller (e.g., a buffer) to access specific memory locations and perform operations at the specified locations. For instance, the command/address (CA) pins allow a memory controller (e.g., a buffer) to select a memory location to access (e.g., bank, row, and/or column for DRAM) and select one or more operations to perform (e.g., read, write, etc.) at the selected memory location. Said another way, the command/address (CA) pins allow a memory controller to select a location, where data is read from or written to using the data (DQ) pins. Additionally or alternatively, the command/address (CA) pins are utilized in training procedures, such as command/address training mode, which optimizes the command/address bus for better signal stability and performance. In one or more implementations, command pins specify a type of command to perform (e.g., read, write, activate, precharge, etc.) while address pins specify the memory location, such as an address (e.g., row, column, bank).

The data strobe (DQS) pins 306 are physical connections that receive or provide the data strobes, which serve as timing reference signals used to synchronize data transfers between memory controllers and the memory chips 126. Unlike a continuous clock signal, the data strobe (DQS) operates as a source-synchronous strobe that toggles (transitions high and low) specifically during data transfer operations to indicate when data on the data (DQ) pins is valid for sampling. Each byte lane of data (e.g., eight data (DQ) lines) typically has its own DQS signal, allowing for precise timing alignment, even at high data transfer rates where timing margins become increasingly tight.

The operation of DQS varies depending on the direction of data transfer. During read operations, the memory chip 126 generates and drives the DQS signal, and the DQS pins 306 provide or otherwise output this strobe in concert with the data (DQ) signals, allowing the memory controller to use the edges of the DQS signal to accurately capture the incoming data with proper timing alignment. Conversely, during write operations, the memory controller generates the DQS signal and drives the DQS to the DQS pins 306 of the memory chip 126. The DQS pins receive this strobe in concert with the data signals, which the memory chip 126 then uses to correctly latch the incoming data based on the DQS edges. This bidirectional approach ensures that the source of the data also provides the timing reference, compensating for potential clock skew and signal integrity issues that may arise in high-speed memory interfaces.

In DDR implementations, both the rising and falling edges of the DQS signal define sampling points for the data bus, effectively doubling the data capture rate. The DQS signal acts as a burst-associated square wave that provides precise synchronization during active data transfers, rather than relying on a global system clock which may suffer from timing variations across the memory interface.

The pins 302, 304, 306 may be connected in a variety of ways to enable data to be read from and written to the memory die 202. In one or more implementations, the memory die 202 belong to ranks, e.g., rank zero (R0) or rank one (R1). Broadly, the ranks define a set of DRAM memory die that are connected to a same chip select and can therefore be accessed simultaneously. The illustrated example includes a first indication 308 and a second indication 310, which may represent a first rank (rank zero-R0) and a second rank (rank one-R1), respectively. In the illustrated example, the inclusion of these ranks indicates one possible division of the memory die 202 between the different ranks. In variations, the memory die 202 may be divided differently among ranks. Alternatively or additionally, there may be a different number of ranks than two, such as one rank, three ranks, and so on.

In accordance with the described techniques, the memory chips 126 are configured to support pseudo channels, which provide a way of logically dividing a single physical channel into multiple independent sub-channels to enable parallelism (and improving efficiency). For example, a pseudo channel may split a physical channel (e.g., a 128-bit wide channel) into two or more logical channels (e.g., two 64-bit pseudo channels). In one or more implementations, each pseudo channel corresponds to a respective command and address (C/A) bus but shares the data bus with other pseudo channels on the same physical channel. This arrangement allows a memory controller to issue commands to one pseudo channel while another pseudo channel is utilized concurrently to transfer data, e.g., performing a memory read or write.

By logically subdividing the physical channel, pseudo channels enable higher bandwidth utilization, as small data transfers do not waste the entire wide data path. This approach also provides higher parallelism by allowing multiple independent streams of memory transactions to overlap, and contributes to lower latency since one pseudo channel can accept commands while another is completing data operations. Notably, the use of pseudo channels can effectively double the number of addressable channels without changing the physical pin count of memory systems, providing increased flexibility in memory chip and system designs while addressing pin count constraints in memory modules.

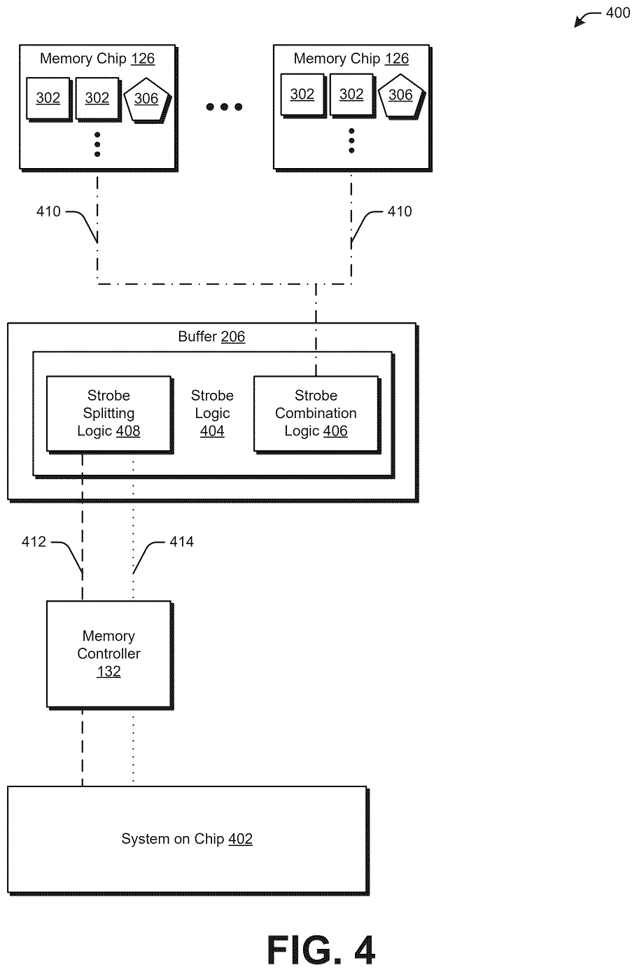

FIG. 4 is a block diagram of a non-limiting example 400 of a buffer configured to combine strobes for multiple pseudo channels into a combined strobe for memory chips and to separate strobes for the multiple pseudo channels for a connected system.

The illustrated example includes two of the memory chips 126 connected to a buffer 206 along with ellipses to indicate that there may be more memory chips 126 connected in variations. The memory chips 126 each include pins 302 (e.g., at least two data pins) and pin 306 (e.g., at least one DQS pin). In this example, the buffer 206 is also connected to system on chip 402 via a memory controller 132. Examples of the system on chip 402 include but are not limited to the processing system 100 as a whole, a central processing unit (CPU), graphics processing unit (GPU), neural processing unit (NPU), and other accelerator units, to name just a few.

The buffer 206 is depicted with strobe logic 404, which in this example includes strobe combination logic 406 and strobe splitting logic 408. The strobe logic 404, including the strobe combination logic 406 and the strobe splitting logic 408, may be implemented in hardware (e.g., circuitry) and/or programmed into the buffer 206, such as when the strobe logic 404 is or includes a field programmable gate array (FPGA). In one or more implementations, the buffer 206 with the strobe logic 404 may be included in a memory chip 126 (e.g., within a DRAM package). When integrated into the memory chip package, the buffer 206 may be implemented as a dedicated die within the stacked memory configuration, or as circuitry integrated directly onto one or more of the memory die 202. Additionally or alternatively, the integrated buffer 206 may share power and ground connections with the memory die 202 and/or utilize the same packaging technology, such as through-silicon vias (TSVs) or wire bonding, to connect to external pins of the memory chip package. In at least one variation, the buffer 206 with the strobe logic 404 is included at the printed circuit board (PCB) level, such as included in the PCB of the memory system 124.

In accordance with the described techniques, the memory chips 126 are configured to support multiple pseudo channels over a single physical channel. In at least one implementation, one or more memory die 202 of a memory chip 126 are logically divided such that a first portion of the die corresponds to a first pseudo channel and a second portion corresponds to a second pseudo channel. From the perspective of the memory controller 132 and the system on chip 402, these pseudo channels operate as independent channels, allowing the memory controller 132 to communicate with different portions of the memory die in parallel and independently.

However, to reduce overall pin count in the memory chips 126, the pseudo channels may share certain signals, including data strobe (DQS) signals provided through the data strobe pins 306. This sharing can create timing complexities when multiple pseudo channels are accessed simultaneously with slight timing offsets. When the memory controller 132 initiates read operations to multiple pseudo channels, for instance, each pseudo channel may need to provide a respective data strobe (DQS) signal at different times. However, these signals are combined into a single shared data strobe signal at the data strobe pin 306. In one or more implementations, the memory chips 126 handle this overlap by extending or adjusting the timing of the combined data strobe signal to accommodate the multiple pseudo channels, ensuring the combined signal appears as a coherent timing reference to the system on chip 402.

The buffer 206 positioned between the memory chips 126 and the system on chip 402 manages different ratios of data pins to strobe pins on each side of the buffer. On the memory chip side, for instance, each memory chip 126 may provide a relatively small number of data pins 302 with corresponding data strobe pins 306, resulting in a low ratio of data pins to strobe pins. However, when the buffer 206 consolidates signals from multiple memory chips 126, the number of data pins per strobe may increase. For example, the buffer 206 may receive signals from multiple memory chips 126, each contributing data pins 302, resulting in a higher consolidated ratio of data pins to strobe signals on the system side. The buffer 206 may be configured to convert between a first ratio of data pins to strobe pins on the memory chip side and a second, different ratio of data pins to strobe pins on the system side, where the first ratio is lower than the second ratio.

By way of example, this conversion process involves consolidating signals from multiple memory chips 126, where each memory chip may contribute data over a small number of data pins 302 (e.g., 2-4 data pins) with a corresponding strobe pin 306, resulting in a low ratio such as 2:1 or 4:1 on the memory chip side. On the system side, though, the buffer 206 may aggregate these signals to provide a higher number of data pins (e.g., 16-32 data pins) per strobe signal, resulting in ratios such as 8:1 or 16:1, thereby reducing the total number of strobe connections required to the system on chip 402.

To address these challenges, the buffer 206 includes strobe logic 404, for example, with strobe combination logic 406 and strobe splitting logic 408 that provide bidirectional strobe management. In the direction from the system on chip 402 to the memory chips 126, the strobe combination logic 406 may combine multiple data strobe signals for separate pseudo channels into the combined data strobe 410 that is utilized by the memory chips 126. During memory write operations, the combined data strobe 410 serves as a timing reference that the memory chips 126 use to latch data received at the data pins 302. The memory controller 132 provides data signals along with separate strobe signals for each pseudo channel to the buffer 206, and the strobe combination logic 406 processes these separate strobes to generate the combined data strobe 410 with appropriate timing to ensure that data from both pseudo channels can be properly latched by the memory chips 126.

In one or more implementations, the buffer 206 adjusts a timing of the combined data strobe 410. This can include extending a duration of the combined data strobe to encompass timing windows of the separate pseudo channels, e.g., when the separate pseudo channels have overlapping data transfer periods. The strobe combination logic 406 may monitor the timing requirements of each pseudo channel and determine an extended duration that covers the earliest start time and latest end time of the data transfer windows across all active pseudo channels. This extension ensures that the combined data strobe 410 remains active for the entire period during which any pseudo channel requires strobe signaling, preventing data corruption that could occur if the strobe signal terminated before all pseudo channels completed their data transfers. The buffer 206 may implement timing control mechanisms that calculate the required extension based on the observed timing offsets between pseudo channels, which may vary depending on the specific memory access patterns and pseudo channel utilization.

In the direction from the memory chips 126 to the system on chip 402, the strobe splitting logic 408 is configured to separate the combined strobe signals into separate data strobe signals per pseudo channel, such as the first-channel data strobe 412 and the second-channel data strobe 414. During memory read operations, the combined data strobe signals from the memory chips 126 are used to validate the timing of data sent over the data pins 302, and the strobe splitting logic 408 separates these combined signals to provide independent timing references for each pseudo channel to the memory controller 132. This approach provides the system on chip 402 with independent strobe signals for each pseudo channel, eliminating concerns about overlapping strobes while maintaining the pin count efficiency benefits on the memory chip side.

Said another way, the strobe combination logic 406, is configured to combine per-pseudo channel data strobes (DQS) in one direction, so that the buffer 206 provides a combined data strobe 410 (combined DQS) shared between multiple pseudo channels to the memory chips 126. In this signal flow direction, the multiple data strobe signals are received by the buffer 206 from the memory controller 132, with each strobe signal corresponding to a different pseudo channel. The strobe combination logic 406 processes these received signals and provides the combined data strobe 410 to at least one of the memory chips 126 connected to the buffer 206. This signal flow enables the memory controller 132 to maintain independent timing control for each pseudo channel while allowing the memory chips 126 to operate with a shared strobe signal, reducing the pin count requirements at the memory chip level.

In contrast, the strobe splitting logic 408 is configured to split the data strobes (DQS) in the other direction (e.g., to the system on chip 402 or “host”), so that the buffer 206 provides a separate data strobe (DQS) signal per pseudo channel to the system on chip 402. In the illustrated example, the separate DQS signals provided to the system on chip 402 include the first-channel data strobe 412 for a first pseudo channel and the second-channel data strobe 414 for a second pseudo channel. In one or more implementations, the strobe splitting logic 408 separates the strobes based on timing differences and logic value differences between the strobes. In at least one implementation, the buffer 206 (e.g., the strobe splitting logic 408) observes command sequences to determine strobe splitting details.

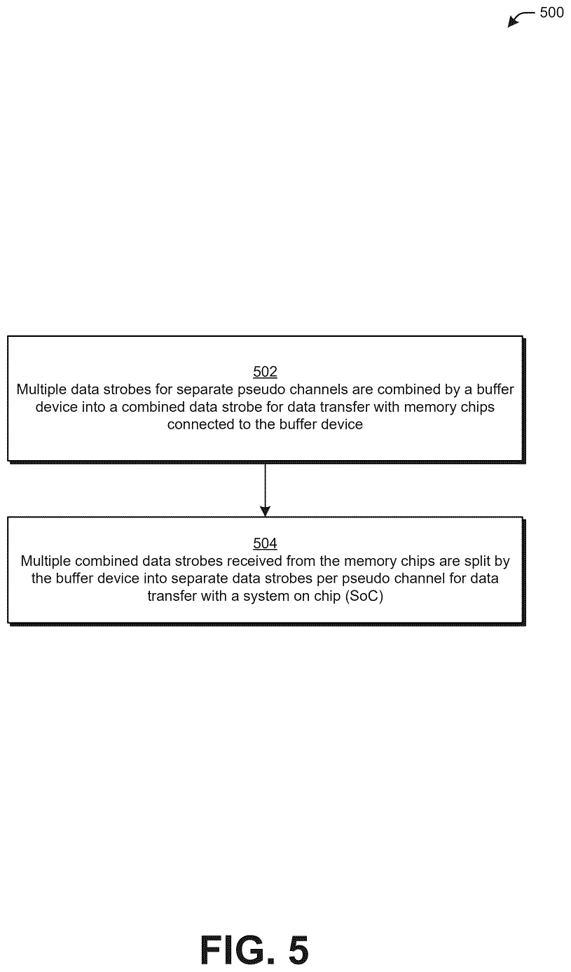

FIG. 5 depicts a procedure 500 in an example implementation of a buffer device for combining and splitting pseudo channel data strobes (DQS).

Multiple data strobes for separate pseudo channels are combined by a buffer device into a combined data strobe for data transfer with memory chips connected to the buffer device (block 502). By way of example, the buffer 206 (e.g., using strobe combination logic 406) combines multiple data strobe signals for separate pseudo channels into a combined data strobe 410 utilized by the memory chips 126 connected to the buffer 206. In one or more implementations, the buffer 206 receives separate data strobe signals from the system on chip 402 via the memory controller 132, where each data strobe signal corresponds to a different pseudo channel within the memory chips 126.

In various scenarios, these data strobe signals are associated with memory write operations where the memory controller 132 provides timing references for data being written with different pseudo channels of the memory chips 126. The buffer 206 (e.g., the strobe combination logic 406) processes these separate signals and generates the combined data strobe 410 that accommodates the timing requirements of both pseudo channels. In one or more implementations, this combining involves extending or adjusting the timing of the combined signal to ensure proper data latching across all utilized pseudo channels while maintaining signal integrity. During these write operations, the combined data strobe 410 is used by the memory chips 126 to latch data received at the data pins 302, where the data is received from the memory controller 132 via the buffer 206. The timing of the combined data strobe 410 is coordinated with the data signals to ensure that the memory chips 126 properly capture and store the incoming data at the appropriate memory locations within the pseudo channels.

Multiple combined data strobes received from the memory chips are split by the buffer device into separate data strobes per pseudo channel for data transfer with a system on chip (SoC) (block 504). By way of example, the buffer 206 receives the combined data strobe 410 from the memory chips 126 and separates the combined data strobe into individual data strobe signals, such as the first-channel data strobe 412 and the second-channel data strobe 414. In one or more implementations, this splitting is performed based on observed command sequences issued to the separate pseudo channels, allowing the strobe splitting logic 408 to determine the appropriate timing and logic value differences between the data strobes.

During memory read operations, for instance, the combined data strobe signals from the memory chips 126 are used to validate data sent over the data pins 302 of the memory chips 126, where the data is sent to the memory controller 132 from the data pins 302. The strobe splitting logic 408 analyzes these combined signals to ensure proper timing validation for each pseudo channel independently. In scenarios involving memory reads, the strobe splitting logic 408 may analyze the combined data strobe signal from the data strobe pins 306 of the memory chips 126 to identify portions corresponding to each pseudo channel. The separate data strobe signals are then provided to the system on chip 402 (e.g., via the memory controller 132), enabling independent timing control for each pseudo channel. This approach eliminates overlapping strobes on the host side while maintaining the pin count efficiency benefits on the memory chip side. The bidirectional nature of the buffer 206 allows the buffer 206 to handle both combining and splitting operations, providing flexibility in managing data strobe signals across different memory operation types.

It is to be appreciated that the figures are not drawn to scale in the illustrated examples, and the various shapes used in the figures to represent various components may differ (perhaps significantly) from the actual shapes of those components in implementation.

What is claimed is:

1. A buffer device, comprising:
strobe combination logic configured to combine multiple data strobes for separate pseudo channels into a combined data strobe utilized by memory chips connected to the buffer device; and
strobe splitting logic configured to split multiple combined data strobes for the separate pseudo channels into separate data strobes per pseudo channel for a system on chip (SoC), wherein the buffer device is configured to provide the separate data strobes per pseudo channel to the SoC.

2. The buffer device of claim 1, wherein the buffer device is included on a dual in-line memory module (DIMM).

3. The buffer device of claim 2, wherein the DIMM supports a multi-channel architecture for accessing the memory chips.

4. The buffer device of claim 1, wherein the buffer device is integrated into a package of a memory chip.

5. The buffer device of claim 1, wherein the combined data strobe is used by the memory chips with a memory write to latch data received at one or more data pins of the memory chips, wherein the data is received from a memory controller.

6. The buffer device of claim 1, wherein the combined data strobe is used with a memory read to validate data sent over one or more data pins of the memory chips, the data sent to a memory controller from the one or more data pins.

7. The buffer device of claim 1, wherein the multiple combined data strobes are received by the buffer device from a memory controller and the combined data strobe is provided to at least one of the memory chips connected to the buffer device.

8. The buffer device of claim 1, wherein the strobe combination logic is configured to adjust timing of the combined data strobe to accommodate timing offsets between the separate pseudo channels.

9. The buffer device of claim 8, wherein adjusting the timing of the combined data strobe comprises extending a duration of the combined data strobe to encompass timing windows of the separate pseudo channels.

10. The buffer device of claim 8, wherein the strobe combination logic is configured to synchronize timing of the multiple data strobes from the separate pseudo channels before combining the multiple data strobes into the combined data strobe.

11. The buffer device of claim 1, wherein the strobe splitting logic is configured to generate the separate data strobes based on observed command sequences issued to the separate pseudo channels.

12. The buffer device of claim 1, wherein the buffer device is configured to convert between a first ratio of data pins to strobe pins on a memory chip side of the buffer device and a second ratio of data pins to strobe pins on a system side of the buffer device, wherein the first ratio is lower than the second ratio to consolidate signals from multiple memory chips.

13. The buffer device of claim 12, wherein a range of the first ratio comprises 2:1 to 4:1 data pins to strobe pins on the memory chip side and a range of the second ratio comprises 8:1 to 16:1 data pins to strobe pins on the system side.

14. A method comprising:
combining, by a buffer device, multiple data strobes for separate pseudo channels into a combined data strobe for data transfer with memory chips connected to the buffer device; and
splitting, by the buffer device, multiple combined data strobes received from the memory chips into separate data strobes per pseudo channel for data transfer with a system on chip (SoC).

15. The method of claim 14, further comprising adjusting a timing of the combined data strobe to accommodate timing offsets between the separate pseudo channels.

16. The method of claim 14, wherein the combined data strobe is used by the memory chips with a memory write operation to latch data received at one or more data pins of the memory chips.

17. The method of claim 14, wherein the combined data strobe is used with a memory read operation to validate data sent over one or more data pins of the memory chips to a memory controller.

18. The method of claim 14, wherein splitting the multiple combined data strobes comprises observing command sequences to determine strobe splitting details based on timing differences and logic value differences between the multiple combined data strobes.

19. A memory system comprising:
one or more memory chips, each memory chip including multiple memory die configured to support multiple pseudo channels, wherein each memory chip includes data pins and data strobe pins; and
a buffer device positioned between the one or more memory chips and a system on chip (SoC), the buffer device configured to:
combine multiple data strobe signals for separate pseudo channels into a combined data strobe signal utilized by the one or more memory chips; and
split data multiple combined strobe signals from the one or more memory chips into separate data strobe signals per pseudo channel for transmission to the SoC.

20. The memory system of claim 19, wherein the one or more memory chips comprise dynamic random-access memory (DRAM) chips arranged in a stacked configuration.
